(19) United States
(12) Patent Application Publication
(10) Pub. No.: US 2010/0154888 A1
(43) Pub. Date: Jun. 24, 2010

(54) Solar Module and Solar Device

(75) Inventor: Serkan Kadi, Osnabruck (DE)

Correspondence Address: GUDRUN E. HUCKETT DRAUDT, SCHUBERTSTR. 15A, WUPPERTAL, 42289, DE

(73) Assignee: SK ENERGY GMBH, Georgsmarienhutte (DE)

(21) Appl. No.: 12/431,863

(22) Filed: Apr. 29, 2009

(30) Foreign Application Priority Data
Dec. 18, 2008 (DE) 20 2008 016 704.3

(51) Int. Cl. H01L 31/00

(52) U.S. Cl. 136/259

(57) ABSTRACT

A solar module for preferably thermal, photovoltaic or highly concentrating photovoltaic solar devices has at least one mirror and a support structure that supports the at least one mirror and secures a shape of the at least one mirror within the solar module. The at least one mirror and the support structure form a composite structure of at least two layers.

The present invention concerns a solar module for preferably thermal, photovoltaic or highly concentrating photovoltaic solar devices, comprising at least one mirror and a support structure that supports and secures the mirror in its shape within the solar module. Moreover, the invention concerns a solar device comprising a corresponding solar module.

Solar devices such as solar-thermal powerplants focus by means of their individual solar modules the impinging light on an absorber pipe that extends along a focal line of a collector and whose contents is heated by the sunlight reflected by the mirrors. This heated medium can be used either directly or indirectly by utilizing heat exchangers for generating steam. Electrical energy is generated with the steam by means of corresponding turbines. Glass mirrors are for example used as mirrors for the solar modules of solar devices which glass mirrors are mounted segmented in a parabolic shape on a metal substructure. In order to enable mounting on the support structure, plastic holders are glued to the back of the glass mirrors and the metal rods of the support structure are screwed thereon. These plastic holders support the mirror in order to secure it in its shape within the solar module. Several mirrors can be combined in a solar module and constitute it with their respective holders.

A disadvantage of this prior art is the metal frame that is to be constructed in a complex way and usually must be manufactured by manual labor. The mirror or mirrors of the conventional solar modules are heavy which places high demands on the support structure or the corresponding carrying structure that must safely hold the mirrors and the support structure even in case of its tracking action. Moreover, the glass mirror and the metal frame have very different thermal expansion coefficients that must be compensated or absorbed by the connecting members.

It is an object of the present invention to improve an afore described solar module with regard to the described disadvantages.

The object is solved by the subject matter according to preamble of claim 1 that is further developed according to its characterizing portion. Moreover, the object is solved by the subject matter according to claim 15.

The solar module according to the invention is characterized in that the mirror and the support structure form an at least two-layered composite structure. Such a composite structure is cantilevered and self-supporting and does not require a point-wise uptake of forces at the corresponding support locations of the segmented glass mirrors. Instead, the preferably unsegmented mirror is supported uniformly across substantial areas of its surface area. The support action of the mirror is realized along the layer formed by the mirror in uniform distribution across the surface area wherein the mirror preferably forms a first layer and the support structure preferably a second layer. The two layers are arranged a really on one another as a composite structure and are secured relative to one another such that the support structure secures the mirror with regard to its shape. The solar module according to the invention therefore represents a self-supporting and shape-maintaining mirror. The solar mirror requires no additional support structures in order to be secured in its preferably parabolic shape.

In one embodiment as a unitary composite structure the mirror can be embodied as a cantilevered and self-supporting mirror also directly with a corresponding support layer that, on the one hand, contributes to the reflection behavior and, on the other hand, is shape-supporting. The support structure is integrated into the mirror. Preferably, the mirror layer however forms an upper cover layer while the support structure forms at least one lower cover layer.

The layers of the mirror and of the support structure are resting areally against one another so that large parts of the mirror layer and in particular the parts that require a support action are underlaid by the shape-maintaining layer of the support structure. Preferably, the two-layer composite is present across the entire upper face or lower face of the mirror.

An especially lightweight solar module is provided according to the invention by a embodiment of the mirror as an aluminum mirror. Such a highly reflective aluminum mirror is significantly lighter than a glass mirror and is able to reflect more than 90% of the impinging sunlight. The term aluminum mirror is to be understood in this context as an optionally coated mirror with a supporting layer of aluminum. Especially advantageous is the use of the mirror as an upper cover layer of the composite structure that, by means of the at least one additional layer, can maintain the mirror in the shape required for the solar module.

Especially advantageous is a sandwich construction of the solar module with an at least three-layered composite structure with an upper cover layer, a lower cover layer, and an intermediately embedded core material as a third layer. Such a sandwich construction provides a very shape-stable and bending-resistant solar module which, without conventional support structures of steel, is provided with mirror surface areas of more than, for example, 5 m².

Especially advantageous is the use of aluminum for all layers of the solar module. While for example an aluminum mirror is formed as an upper cover layer, the lower cover layer can also be produced of aluminum sheet. Both aluminum sheets are then connected by an intermediately embedded core material also made of aluminum. The components of the solar module thus have in this way identical expansion properties, the mirrors can be mass-produced automatically, and they are insensitive with regard to corrosion and moisture. The carrying layer that is arranged as the support layer between the upper and lower cover layers is suitable in particular in the form of a corrugated structure for a curved mirror construction. A corrugated structure is expedient as a structural reinforcement especially for curved solar modules because it can stiffen in a simple and effective way the aluminum mirror.

Instead of the use of aluminum, corrosion-resistant material, for example, galvanized steel or alloys of aluminum with other elements, can be used in a similar way.

In addition to a core structure that in cross-section is corrugated, also a core structure can be provided alternatively or additionally that is embodied like elongate honeycombs, i.e., hexagonal. This core structure is also very shape-stable and bending-resistant wherein the shape-providing intermediate layer is to be particularly milled out of the honeycomb material.

Other core material that is of a regular structure can also be expediently employed inasmuch as the corrugated or honeycomb intermediate layer can distribute well the forces to be absorbed.

The longitudinal extension along the peaks of the corrugated structure, like the longitudinal extension of the honeycomb structure, is to be arranged preferably in the longitudinal direction of the solar module, i.e., they extend transversely to the curvature of the preferably unidirectionally curved or parabolically curved bowl.

Preferably, the solar module according to the invention is produced by gluing the composite or sandwich layers. For example, by means of a thermal adhesive method the corrugated or honeycomb supporting structure of core material is applied to the lower cover plate or layer, the curvature of the bowls can then be matched to the desired profile of the solar module by simple machining steps. Subsequently, an aluminum mirror is to be applied in a further processing step onto the core material wherein the entire composite structure with the not yet fixedly adhesively connected layers is pressed into a specified mold. From it, after curing of the adhesive, the self-supporting aluminum mirror can be removed.

The support structure is preferably embodied by means of an actuator means for arranging the mirror on a support frame. As a result of the lightweight construction of the solar module, the frame can be designed to be significantly less strong. The actuator means for movably arranging the solar module on the support frame comprises, for example, a hydraulically controllable actuator system.

In a further embodiment, the composite structure comprises a highly reflective aluminum mirror as an upper cover layer, a stabilizing fiberglass bottom side as a lower cover layer as well as an intermediately arranged fiber-containing fiberglass foam that also provides a stable self-supporting solar module unit.

In a further advantageous embodiment with only two layers, the aluminum mirror can form an upper cover layer while the second layer of the support structure that receives and distributes the forces is provided with a corrugated cross-sectional profile. Depending on the application of the mirror and the size thereof, such a two-layer composite structure is sufficiently stable.

Further advantages and details of the invention will be apparent from the following Figure description. It is schematically illustrated in:

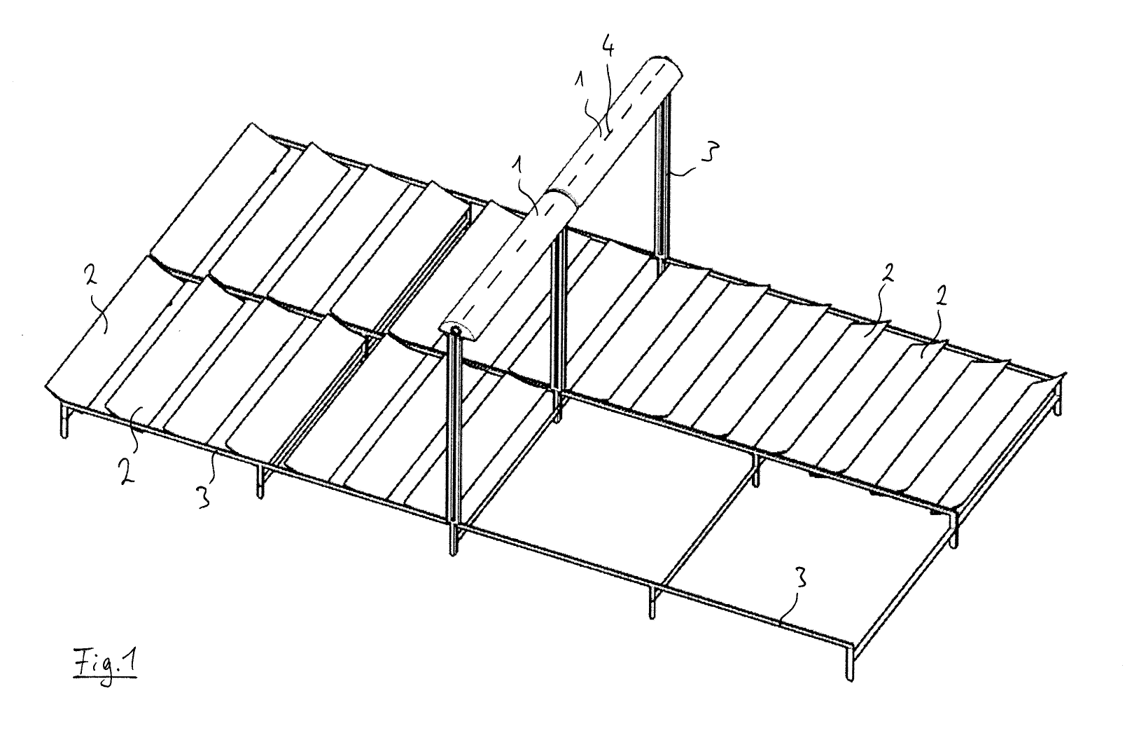

FIG. 1 a solar device according to the invention;

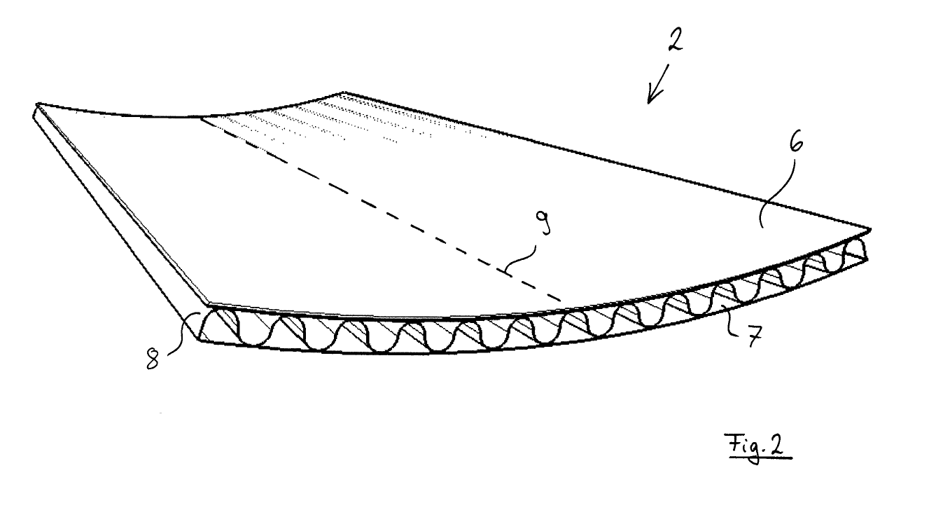

FIG. 2 a solar module according to the invention;

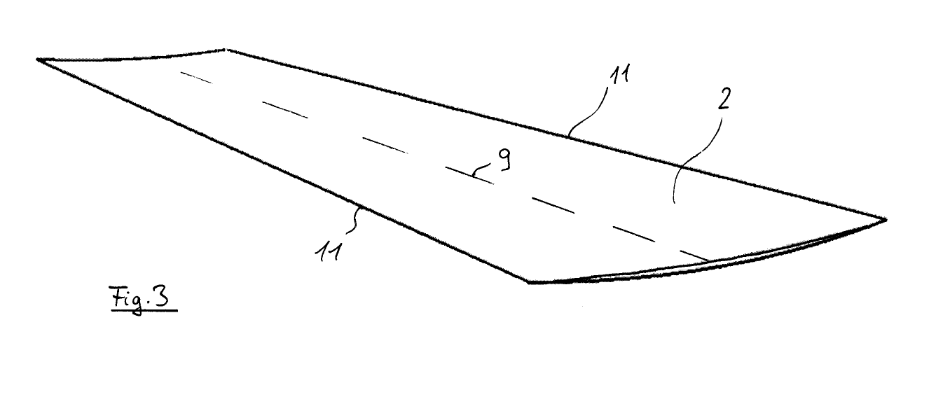

FIG. 3 the object of FIG. 2 in a further embodiment;

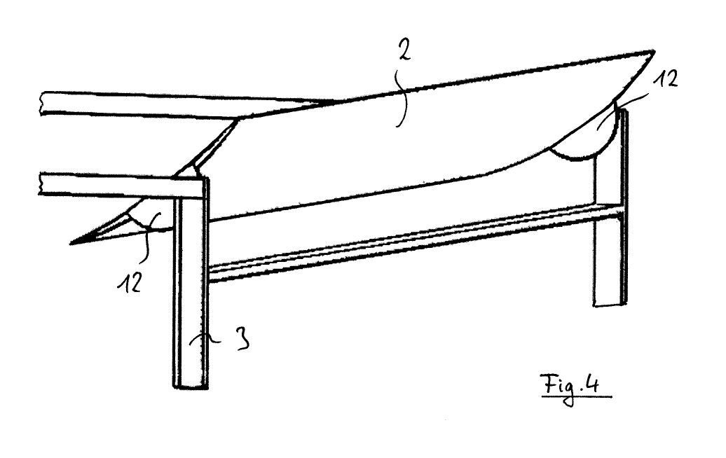

FIG. 4 a detail of the solar device according to FIG. 1;

FIG. 5 the object of FIG. 2 in a detail view;

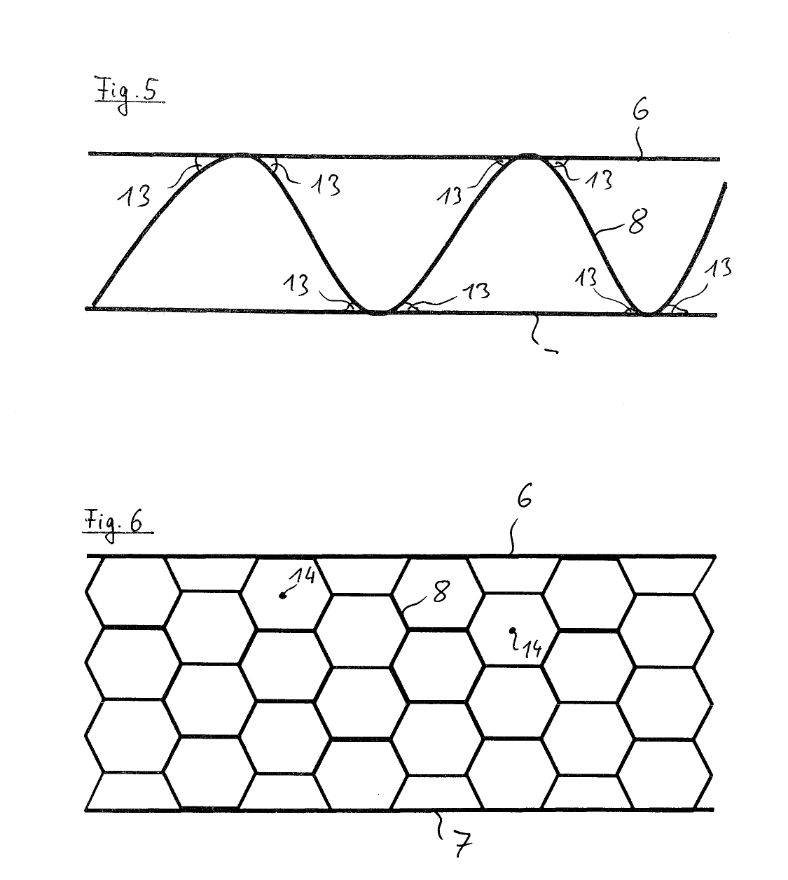

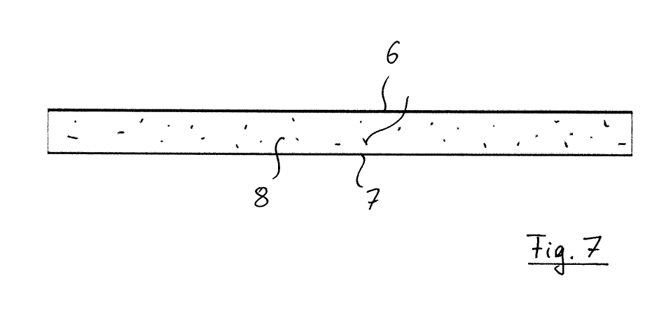

FIG. 6 a detail of a further solar module according to the invention;

FIG. 7 a detail of a further solar module according to the invention.

Same parts or parts acting the same, inasmuch as helpful, are provided with identical reference numerals. Individual technical features of the embodiments described in the following together with the features of afore described embodiments can also result in embodiments according to the invention.

A solar device according to FIG. 1 comprises two receivers 1 that receive sunlight reflected by a plurality of solar modules 2 according to the invention. The solar modules 2 are arranged in two rows on a support frame 3 which is arranged on opposite sides of a longitudinal axis 4. The shape-stable and bending-resistant solar modules 2 can be attached without complex carrying or substructures directly by means of actuator means on the support frame 3. The entire solar device is thus, on the one hand, more lightweight as a whole; on the other hand however, it is also significantly faster to assemble as a result of the reduced number of parts to be connected to one another.

A solar module 2 according to the invention is explained in more detail in FIG. 2 and comprises an aluminum mirror as an upper cover layer 6, an aluminum sheet as a lower cover layer 7 as well as a core material 8 also of aluminum and structured to have a corrugated profile. The thus formed composite structure is self-supporting and shape-stable which is advantageous in particular for the illustrated parabolically shaped mirror. The latter can be arranged with elimination of complex support structures directly on the support frame 3.

The thickness of the layers is variable depending on the application. Preferably, the thickness of the aluminum mirror layer that reflects e.g. 95% of the impinging sunlight is, for example, between 0.5 to 0.8 mm. The thickness of the lower cover layer 7 is also preferably 0.5 to 0.8 mm. The thickness of the corrugated profile 8 is also approximately 0.5 mm wherein however the thickness of the material and not the thickness of the layer, measured between valley and peak, is meant. Preferably, the solar modules are produced as curvature-free straight solar modules or with a focal point between 2.5 and 14 m. The weight of the solar modules produced in sandwich construction is preferably between 4 and 10 kg/m², preferably between 4 and 6, in particular between 5 to 6 kg/m². The thickness of the composite structure as a whole is between 0.5 to 1.5 cm, preferably approximately 1 cm. Solar mirrors of this lightweight sandwich construction can withstand without difficulty greater wind loads as they may exist for example in desert regions.

The solar module according to FIG. 3 has in comparison to the solar module according to FIG. 2 a somewhat different shape. The thickness of the composite structure according to FIG. 3 varies in order to use less material in the outer area of the mirror toward the edges and in order to become more lightweight. Thus, the thickness of the center in the area of the longitudinal axis 9 is greater than at the lateral edges 11.

According to FIG. 4, the solar module 2 according to the invention is a self-supporting construction that is arranged by means of actuator means 12 directly on the support frame 3. By means of the actuator means 12 tracking of the sun is carried out during the day and optionally also during the annual cycle. In this connection, the solar modules 2 or aluminum mirrors produced in sandwich construction are sufficiently stiff and weather-resistant in order to withstand the demands in climatically very unstable regions.

FIG. 5 discloses a detail of the solar module according to the invention according to FIG. 2 wherein the adhesive connections 13 that have been applied during manufacture of the module 2 are illustrated somewhat over-proportional. The curing of the adhesive connections 13 between the extremes of the corrugated profile 8 and the lower cover layer 7 as well as the upper cover layer 6 that are located relative to one another at a certain relative position results in the parabolic shape illustrated in FIG. 2.

In the variant according to FIG. 6, an embodiment with a honeycomb core material 7 is disclosed. In this connection, the only partially indicated longitudinal axes 14 of the honeycomb material extend parallel to the longitudinal axis 9 of the embodiment shown e.g. in FIG. 3.

The preferred orientation of the core material or of the intermediate layer is not disclosed in the embodiment according to FIG. 7. In this embodiment, a layer of fiberglass foam comprising fibers 15 is used as a core material 8 and a layer of fiberglass is used as a lower cover layer 7.

What is claimed is:

1.-15. (canceled)

16. A solar module for preferably thermal, photovoltaic or highly concentrating photovoltaic solar devices, the solar module comprising:
at least one mirror;
a support structure that supports the at least one mirror and secures a shape of the at least one mirror within the solar module;
wherein the at least one mirror and the support structure form a composite structure comprising at least two layers.

17. The solar module according to claim 16, wherein the at least one mirror is an aluminum mirror.

18. The solar module according to claim 16, wherein the at least one mirror forms an upper cover layer of the composite structure.

19. The solar module according to claim 16, wherein the composite structure comprises an upper cover layer, a lower cover layer, and a core material as a third layer, which core material is intermediately embedded between the upper cover layer and the lower cover layer.

20. The solar module according to claim 19, wherein the core material has a regular structure.

21. The solar module according to claim 20, wherein the core material is selected from a corrugated structure or a honeycomb structure.

22. The solar module according to claim 19, wherein at least one of the upper and lower cover layers comprises an aluminum sheet.

23. The solar module according to claim 19, wherein the core material is comprised of aluminum.

24. The solar module according to claim 16, wherein the at least one mirror forms an at least unidirectionally curved bowl.

25. The solar module according to claim 19, wherein the core material has a corrugated structure and wherein peaks of the corrugated structure extend in a direction of longitudinal extension of the solar module.

26. The solar module according to claim 19, wherein the core material has a honeycomb structure and wherein longitudinal axes of the honeycombs of the honeycomb structure extend in a direction of longitudinal extension of the solar module.

27. The solar module according to claim 16, wherein the support structure is embodied for arranging the at least one mirror on a support frame.

28. The solar module according to claim 16, comprising at least one actuator means adapted to movably arrange the solar module on a support frame.

29. The solar module according to claim 16, wherein a thickness of the composite structure is reduced toward one side of the composite structure.

30. The solar module according to claim 16, wherein the composite structure comprises a layer of fiberglass and a layer of fiber-containing fiberglass foam.

31. The solar module according to claim 16, wherein the composite structure comprises a layer of fiberglass.

32. The solar module according to claim 16, wherein the composite structure comprises a layer of fiber-containing fiberglass foam.

33. A solar device comprising:
a support frame;
a receiver;
at least one solar module according to claim 16, wherein the at least one solar module is arranged on the support frame and adapted to reflect sunlight onto the receiver.
